(19) United States
(12) Patent Application Publication
(10) Pub. No.: US 2024/0355966 A1
(43) Pub. Date: Oct. 24, 2024

(54) BACKLIGHT MODULES, DISPLAY MODULES, AND SPLICING DISPLAY DEVICES

(71) Applicant: Wuhan China Star Optoelectronics Technology Co., Ltd.

(72) Inventors: Ze ZHANG, Wuhan, Hubei (CN); Lei ZHU, Wuhan, Hubei (CN)

(73) Assignee: Wuhan China Star Optoelectronics Technology Co., Ltd., Wuhan, Hubei (CN)

(21) Appl. No.: 18/039,295

(22) PCT Filed: Apr. 18, 2023
(86) PCT No.: PCT/CN2023/088878

§ 371 Date: May 30, 2023

(30) Foreign Application Priority Data
Mar. 30, 2023 (CN) 202310347721.9

(51) Int. Cl. H01L 33/24; H01L 25/075; H01L 33/08

(52) U.S. Cl. CPC H01L 33/24; H01L 25/0753; H01L 33/08

(57) ABSTRACT

The present disclosure discloses a backlight module, a display module, and a splicing display device. The backlight module includes a central light-emitting area and an edge light-emitting area disposed at a side of the central light-emitting area along a first direction; the central light-emitting area is provided with a plurality of first light-emitting units, and the edge light-emitting area is provided with a plurality of second light-emitting units; a direction from a center to an edge of the backlight module is defined as the first direction, and a distance between adjacent two first light-emitting units is greater than a distance between adjacent two second light-emitting units in the first direction.

### TECHNICAL FIELD

The present disclosure relates to the technical field of display, in particular to backlight modules, display modules, and splicing display devices.

### BACKGROUND

In recent years, micro light-emitting diodes (Micro LEDs) technology and mini light-emitting diodes (Mini LEDs) technology have attracted attention from consumer markets. Compared with organic light-emitting diodes (OLEDs) technology, the Micro LEDs technology and the Mini LEDs technology have significant advantages in power consumption, dynamic display, display brightness, and product reliability. In backlight modules using the Micro LEDs or the Mini LEDs as light-emitting units, due to luminescent characteristics of the Micro LEDs and the Mini LEDs, energy of light at central areas is relatively high, which easily leads to insufficient brightness at edge areas, resulting in dark edges of display devices applying the above-mentioned backlight modules.

Therefore, a backlight module, a display module, and a splicing display device are urgently needed to solve the above-mentioned technical problem.

### Technical Problems

The present disclosure provides a backlight module, a display module, and a splicing display device, to alleviate a technical problem of dark edges caused by insufficient brightness at edge areas of existing backlight modules.

### Technical Solutions

To solve the above-mentioned problem, technical solutions provided by the present disclosure are as following.

An embodiment of the present disclosure provides a backlight module including a central light-emitting area and an edge light-emitting area disposed at a side of the central light-emitting area along a first direction, and the backlight module includes:
a plurality of first light-emitting units disposed in the central light-emitting area; and
a plurality of second light-emitting units disposed in the edge light-emitting area;
in which a direction from a center of the backlight module to an edge of the backlight module is defined as the first direction, and a distance between adjacent two of the first light-emitting units along the first direction is greater than a distance between adjacent two of the second light-emitting units along the first direction.

In some embodiments, the distance between the adjacent two of the second light-emitting units along the first direction gradually decreases.

In some embodiments, distances between every adjacent two of the first light-emitting units along the first direction are equal.

In some embodiments, the central light-emitting area includes at least one first rectangular light area, four of the first light-emitting units are respectively located at four corners of the first rectangular light area, and none of the first light-emitting units is disposed in the first rectangular light area; and the first rectangular light area is in a square shape.

In some embodiments, the edge light-emitting area includes at least one second rectangular light area adjacent to the central light-emitting area, four of the second light-emitting units are respectively located at four corners of the second rectangular light area, and none of the second light-emitting units is disposed in the second rectangular light area; a length of a side of the second rectangular light area along the first direction is less than a length of a side of the second rectangular light area along a direction perpendicular to the first direction; and the length of the side of the second rectangular light area along the direction perpendicular to the first direction is equal to a length of each side of the first rectangular light area.

In some embodiments, the length of each side of the first rectangular light area is defined as A, and the length of the side of the second rectangular light area along the first direction is defined as b;
in which A and b satisfy the following equation:

$$\frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{\sqrt{{( 3 A )}^{2} + {( 2 A + b )}^{2}}} = \frac{2}{\sqrt{{A}^{2} + {A}^{2}}} + \frac{4}{\sqrt{{( 3 A )}^{2} + {A}^{2}}} + \frac{2}{\sqrt{{( 3 A )}^{2} + {( 3 A )}^{2}}} .$$

In some embodiments, the edge light-emitting area also includes at least one third rectangular light area adjacent to the second rectangular light area and located at a side of the second rectangular light area away from the central light-emitting area; four of the second light-emitting units are respectively located at four corners of the third rectangular light area, and none of the second light-emitting units is disposed in the third rectangular light area;
in which a length of a side of the third rectangular light area along the first direction is defined as c, and A, b, and c satisfy the following equation:

$$\frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{{( 3 A )}^{2} + {( 2 A + b )}^{2}} = \frac{2}{\sqrt{{A}^{2} + {c}^{2}}} + \frac{1}{\sqrt{{( 2 b + c )}^{2} + {A}^{2}}} + \frac{2}{\sqrt{{( 3 A )}^{2} + {( c )}^{2}}} + \frac{1}{\sqrt{{( 3 A )}^{2} + {( 2 b + c )}^{2}}} .$$

In some embodiments, the central light-emitting area includes at least one first regular hexagonal light area, six of the first light-emitting units are respectively located at six corners of the first regular hexagonal light area, and none of the first light-emitting units is disposed in the first regular hexagonal light area; and the edge light-emitting area includes at least one second regular hexagonal light area, six of the second emitting units are respectively located at six corners of the second regular hexagonal light area, and none of the second light-emitting units is disposed in the second regular hexagonal light area; a length of any side of the first regular hexagonal light area is greater than a length of any side of the second regular hexagonal light area.

In some embodiments, the central light-emitting area includes at least one first regular triangle light area, three of the first light-emitting units are respectively located at three corners of the first regular triangle light area, and none of the first light-emitting units is disposed in the first regular triangle light area; and the edge light-emitting area includes at least one second regular triangle light area, three of the second light-emitting units are respectively located at three corners of the second regular triangle light area, and none of the second light-emitting units is disposed in the second regular triangle light area; a length of any side of the first regular triangle light area is greater than a length of any side of the second regular triangle light area.

In some embodiments, a light shape of the second light-emitting units is in an ellipsoid shape; the backlight module includes at least a first edge, and an included angle between the first edge and a long axis of the light shape corresponding to one of the second light-emitting units is less than or equal to 5 degrees in a top view direction of the backlight module.

An embodiment of the present disclosure also provides a display module including a backlight module, and the backlight module includes a central light-emitting area and an edge light-emitting area disposed at a side of the central light-emitting area along a first direction, and includes:
a plurality of first light-emitting units disposed in the central light-emitting area; and
a plurality of second light-emitting units disposed in the edge light-emitting area;
in which a direction from a center of the backlight module to an edge of the backlight module is defined as the first direction, and a distance between adjacent two of the first light-emitting units along the first direction is greater than a distance between adjacent two of the second light-emitting units along the first direction.

In some embodiments, the distance between the adjacent two of the second light-emitting units along the first direction gradually decreases.

In some embodiments, distances between every adjacent two of the first light-emitting units along the first direction are equal.

In some embodiments, the central light-emitting area includes at least one first rectangular light area, four of the first light-emitting units are respectively located at four corners of the first rectangular light area, and none of the first light-emitting units is disposed in the first rectangular light area; and the first rectangular light area is in a square shape.

In some embodiments, the edge light-emitting area includes at least one second rectangular light area adjacent to the central light-emitting area, four of the second light-emitting units are respectively located at four corners of the second rectangular light area, and none of the second light-emitting units is disposed in the second rectangular light area; a length of a side of the second rectangular light area along the first direction is less than a length of a side of the second rectangular light area along a direction perpendicular to the first direction; and the length of the side of the second rectangular light area along the direction perpendicular to the first direction is equal to a length of each side of the first rectangular light area.

In some embodiments, the central light-emitting area includes at least one first regular hexagonal light area, six of the first light-emitting units are respectively located at six corners of the first regular hexagonal light area, and none of the first light-emitting units is disposed in the first regular hexagonal light area; the edge light-emitting area includes at least one second regular hexagonal light area, six of the second emitting units are respectively located at six corners of the second regular hexagonal light area, and none of the second light-emitting units is disposed in the second regular hexagonal light area; and a length of any side of the first regular hexagonal light area is greater than a length of any side of the second regular hexagonal light area.

In some embodiments, the central light-emitting area includes at least one first regular triangle light area, three of the first light-emitting units are respectively located at three corners of the first regular triangle light area, and none of the first light-emitting units is disposed in the first regular triangle light area; and the edge light-emitting area includes at least one second regular triangle light area, three of the second light-emitting units are respectively located at three corners of the second regular triangle light area, and none of the second light-emitting units is disposed in the second regular triangle light area; a length of any side of the first regular triangle light area is greater than a length of any side of the second regular triangle light area.

In some embodiments, a light shape of the second light-emitting units is in an ellipsoid shape; the backlight module includes at least a first edge, and an included angle between the first edge and a long axis of the light shape corresponding to one of the second light-emitting units is less than or equal to 5 degrees in a top view direction of the backlight module.

An embodiment of the present disclosure also provides a splicing display device which includes at least two spliced display modules; each of the display modules includes a backlight module including a central light-emitting area and an edge light-emitting area disposed at a side of the central light-emitting area along a first direction, and the backlight module includes:
a plurality of first light-emitting units disposed in the central light-emitting area; and
a plurality of second light-emitting units disposed in the edge light-emitting area;
in which a direction from a center of the backlight module to an edge of the backlight module is defined as the first direction, and a distance between adjacent two of the first light-emitting units along the first direction is greater than a distance between adjacent two of the second light-emitting units along the first direction.

In some embodiments, the distance between the adjacent two of the second light-emitting units along the first direction gradually decreases.

### Beneficial Effects

By designing a distance of the light-emitting units including the second light-emitting units at the edge light-emitting area being less than a distance of the light-emitting units including the first light-emitting units at the central light-emitting area along the direction from the center to the edge of the backlight module, the present disclosure can improve luminous energy of the edge light-emitting area to enhance brightness of the edge light-emitting area, thereby improving an overall quality of display images.

### BRIEF DESCRIPTION OF THE DRAWINGS

FIG. 1 is a schematic top view diagram of a first structure of a backlight module provided by an embodiment of the present disclosure.

FIG. 2 is a schematic partial top view diagram of a second structure of a backlight module provided by an embodiment of the present disclosure.

FIG. 3 is a schematic partial top view diagram of a third structure of a backlight module provided by an embodiment of the present disclosure.

FIG. 4 is a schematic top view diagram of a fourth structure of a backlight module provided by an embodiment of the present disclosure.

FIG. 5 is a schematic top view diagram of a fifth structure of a backlight module provided by an embodiment of the present disclosure.

FIG. 6 is a schematic structural diagram of a display module provided by an embodiment of the present disclosure.

FIG. 7 is a schematic structural diagram of a splicing display device provided by an embodiment of the present disclosure.

### DETAILED DESCRIPTION

The present disclosure provides a backlight module, a display module, and a splicing display device. The present disclosure will be described in detail with reference to attached figures and in combination with embodiments in the following, so as to make a purpose, technical solutions, and effects of the present disclosure clearer. It should be understood that specific embodiments described here are only used to explain the present disclosure and are not intended to limit it.

The present disclosure provides a backlight module, a display module, and a splicing display device. The following will describe in detail. It should be noted that a description order of the following embodiments does not serve as a limitation on a preferred order of the embodiments.

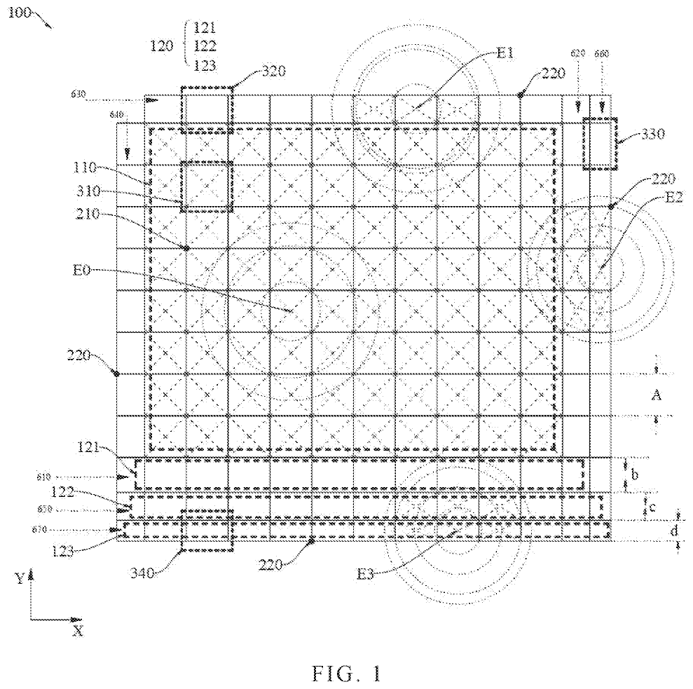

Please refer to FIG. 1 to FIG. 5, embodiments of the present disclosure provide a backlight module 100 including a central light-emitting area 110 and an edge light-emitting area 120 disposed at a side of the central light-emitting area 110 along a first direction, and the backlight module 100 includes:
a plurality of first light-emitting units 210 disposed in the central light-emitting area 110; and
a plurality of second light-emitting units 220 disposed in the edge light-emitting area 120;
a direction from a center of the backlight module 100 to an edge of the backlight module 100 is defined as the first direction, and a distance between adjacent two first light-emitting units 210 along the first direction is greater than a distance between adjacent two second light-emitting units 220 along the first direction.

By designing a distance of the second light-emitting units at the edge light-emitting area being less than a distance of the first light-emitting units at the central light-emitting area along the direction from the center to the edge of the backlight module, the present disclosure can improve luminous energy of the edge light-emitting area to enhance brightness of the edge light-emitting area, thereby improving an overall quality of display images.

Technical solutions of the present disclosure are described in combination with specific embodiments.

In an embodiment, please refer to FIG. 1, the backlight module 100 is provided with the central light-emitting area 110 and the edge light-emitting area 120 disposed at the side of the central light-emitting area 110 along the first direction, and includes the plurality of first light-emitting units 210 disposed in the central light-emitting area 110 and the plurality of second light-emitting units 220 disposed in the edge light-emitting area 120. The direction from the center of the backlight module 100 to the edge of the backlight module 100 is defined as the first direction, and the distance between adjacent two first light-emitting units 210 along the first direction is greater than the distance between adjacent two second light-emitting units 220 along the first direction.

If current of the first light-emitting units 210 and current of the second light-emitting units 220 are the same, that is, energy of light emitted by the first light-emitting units 210 and energy of light emitted by the second light-emitting units 220 are the same. Since light radiation energy is inversely proportional to a distance between light-emitting units, the farther away from a center of the light emitting units, the smaller the light radiation energy. Therefore, as a distance from a center to an edge of the backlight module increases, that is, in the direction from the center of the backlight module to the edge of the backlight module, by designing the distance between adjacent two first light-emitting units 220 at the edge light-emitting area being greater than the distance between adjacent two second light-emitting units 210 at the central light-emitting area 110, luminous energy at any position of the edge light-emitting area 120 can be improved, so as to enhance brightness of the edge light-emitting area 120, thereby improving the overall quality of display images.

In the present disclosure, a shape of each light area represents an outer contour shape of the light area. A direction of X-axis in the figures is defined as a row direction, a direction of Y-axis in the figures is defined as a column direction, and the first direction is that the center of the backlight module points perpendicular to each side of the backlight module. For example, the first direction corresponding to a lower side of the backlight module is a negative direction of the Y-axis, the first direction corresponding to a left side of the backlight module is a negative direction of the X-axis, the first direction corresponding to an upper side of the backlight module is a positive direction of the Y-axis, and the first direction corresponding to a right side of the backlight module is a positive direction of the X-axis, as explained here.

In some embodiments, please refer to FIG. 1, the distance between adjacent two second light-emitting units 220 along the first direction gradually decreases.

The closer an area is to the edge of the backlight module 100, the less the distance between adjacent two second emitting units 220 along the first direction, which can reduce a difference of brightness between an edge area of the backlight module 100 and a center area of the backlight module 100, so as to improve luminous energy at any position of the edge light-emitting area 120 to enhance brightness of the edge light-emitting area 120, thereby improving the overall quality of display images.

In some embodiments, please refer to FIG. 1, distances between every adjacent two first light-emitting units 210 along the first direction are equal.

That is, distances of the first light-emitting units 210 at the central light-emitting area 110 are equal, so as to ensure uniform brightness of the central light-emitting area 110.

In some embodiments, please refer to FIG. 1 to FIG. 4. The central light-emitting area 110 includes at least one first rectangular light area 310, four first light-emitting units 210 are respectively located at four corners of the first rectangular light area 310, and none of the first light-emitting units 210 is disposed in the first rectangular light area 310. The first rectangular light area 310 is in a square shape.

The first light-emitting units 210 at the central light-emitting area 110 is arranged in a square array, so as to ensure uniform brightness of the central light-emitting area 110.

In some embodiments, please refer to FIG. 1 to FIG. 4, the edge light-emitting area 120 includes at least one second rectangular light area 320 adjacent to the central light-emitting area 110, four second light-emitting units 220 are respectively located at four corners of the second rectangular light area 320, and none of the second light-emitting units 220 is disposed in the second rectangular light area 320. A length of a side of the second rectangular light area 320 along the first direction is less than a length of a side of the second rectangular light area 320 along a direction perpendicular to the first direction which is equal to a length of each side of the first rectangular light area 310.

For example, the edge light-emitting area 120 includes a first sub area 121 adjacent to the central light-emitting area 110 and including a plurality of the second rectangular light areas 320. A distance between adjacent two second light-emitting units 220 is less than a distance between adjacent two first light-emitting units 210 in a direction perpendicular to the edge of the backlight module.

The second rectangular light areas 320 can be arranged in a single row along the row direction of the central light-emitting area 110, and/or arranged in a single column along the column direction of the central light-emitting area 110. Distances of the light-emitting units decrease along a direction from the central light-emitting area 110 to the edge of the backlight module 100, which can improve luminous energy at any position of the edge light-emitting area 120 to enhance brightness of the edge light-emitting area 120, thereby improving the overall quality of display images.

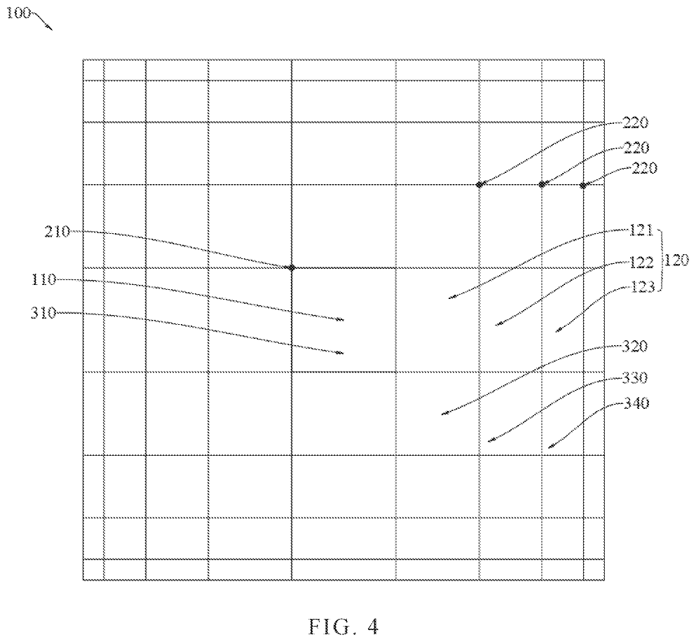

A quantity of light areas of the central light-emitting area 110 can be designed according to actual requirements. For example, please refer to FIG. 4, the central light-emitting area 110 may only include one first rectangular light area 310, and a plurality of edge areas including the first sub area 121 and a second sub area 122 can be designed at periphery of the first rectangular light area 310, thereby enabling the distances of the light-emitting units to decrease gradually along the direction from the center of the backlight module to a surrounding area of the backlight module, so as to further optimize light energy density, thereby improving the overall quality of display images. Further, for example, please refer to FIG. 1, the central light-emitting area 110 may include a plurality of first rectangular light areas 310 and only one first sub area 121 which surrounds the central light-emitting area 110; compared with a equidistant design of the light-emitting units in existing backlight modules, only one ring of the light-emitting units at an outermost area needs to be moved inward to enhance the brightness of the edge light emitting area 120, thereby improving the overall quality of display images.

In some embodiments, please refer to FIG. 1, the central light-emitting area 110 includes the plurality of first rectangular light areas 310 arranged in a matrix, and lengths of all sides of the first rectangular light area 310 are equal and defined as A. The first sub area 121 includes a first side 610, a second side 620, a third side 630, and a fourth side 640. An extension direction of the first side 610 is parallel to an extension direction of the third side 630, an extension direction of the second side 620 is parallel to an extension direction of the fourth side 640, and the extension direction of the first side 610 is perpendicular to the extension direction of the second side 620. Lengths of corresponding sides of the second rectangular light area 320 in an extension direction parallel to a side of the first sub area 121 are equal that are A. A length of a side of the second rectangular light area 320 along the first direction is defined as b, for example, lengths of corresponding sides of the second rectangular light area 320 in the extension direction perpendicular to the side of the first sub area 121 are equal that are b.

A and b satisfy a following equation:

$$\frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{\sqrt{{( 3 A )}^{2} + {( 2 A + b )}^{2}}} = \frac{2}{\sqrt{{A}^{2} + {A}^{2}}} + \frac{4}{\sqrt{{( 3 A )}^{2} + {A}^{2}}} + \frac{2}{\sqrt{{( 3 A )}^{2} + {( 3 A )}^{2}}} .$$

For example, the first side 610 and the third side 630 extend along the row direction, and the second side 620 and the fourth side 640 extend along the column direction. Lengths of sides of each second rectangular light area 320 corresponding to the first side 610 and the third side 630 in the row direction are equal to the length of each side of the first rectangular light area 310 that is defined as A; lengths of sides of each second rectangular light area 320 corresponding to the first side 610 and the third side 630 in the column direction are less than the length of each side of the first rectangular light area 310 and are b. Lengths of sides of each second rectangular light area 320 corresponding to the second edge 620 and the fourth edge 640 in the column direction are equal to the length of each side of the first rectangular light area 310 that is defined as A; lengths of sides of each second rectangular light area 320 corresponding to the second edge 620 and the fourth edge 640 in the row direction are less than the length of each side of the first rectangular light area 310 and are b.

Energy at a geometric center of the first rectangular light area 310 close to a central area of the central light-emitting area 110 is defined as E0, and E0 satisfies a following equation:

$$E 0 = \frac{4 k}{0.5 \sqrt{{A}^{2} + {A}^{2}}} + \frac{8 k}{0.5 \sqrt{{( 3 A )}^{2} + {A}^{2}}} + \frac{4 k}{0.5 \sqrt{{( 3 A )}^{2} + {( 3 A )}^{2}}} .$$

Energy at a geometric center of the second rectangular light area 320 of the first sub area 121 is defined as E1, E1 satisfies a following equation:

$$E 1 = \frac{4 k}{0.5 \sqrt{{A}^{2} + {b}^{2}}} + \frac{2 k}{0.5 \sqrt{{( 2 A + b )}^{2} + {A}^{2}}} + \frac{4 k}{0.5 \sqrt{{( 3 A )}^{2} + {( b )}^{2}}} + \frac{2 k}{0.5 \sqrt{{( 3 A )}^{2} + {( 2 A + b )}^{2}}} ,$$

k is a coefficient constant, and E1=E0.

Model settings:
a hypothetical definition: lamps have the same current, that is, energy of light emitted by the lamps are the same, and the light is distributed in a circular shape; light radiation energy is inversely proportional to a distance between the lamps, the farther away from a center of the lamps, the smaller the light radiation energy; the light radiation energy is defined as E, k is a coefficient that is a constant value, a distance between the lamps at simulated points is defined as X, and k and X is defined to satisfy a following equation:

$${lim}_{x \to 0} \frac{k}{X} = k , and {lim}_{X \to + ∞} \frac{k}{X} = 0 .$$

Center energy at the central light-emitting area 110 of a light board is defined as E0, when a quantity of gradient levels at the edge light-emitting area 120 is defined as n, there are n levels of center energy at the edge light-emitting area from a farthest edge to the central light-emitting area, center energy at the edge light-emitting area is defined as En, En-1, En-2 . . . E1, respectively, and n is greater than or equal to 1.

When n is equal to 0, an equation for calculating center energy at the central light-emitting area 110 satisfies a following equation:

$$E 0 = \frac{4 k}{0.5 \sqrt{{A}^{2} + {A}^{2}}} + \frac{8 k}{0.5 \sqrt{{( 3 A )}^{2} + {A}^{2}}} + \frac{4 k}{0.5 \sqrt{{( 3 A )}^{2} + {( 3 A )}^{2}}} .$$

When n is equal to 1, that is, only one gradient level at the edge light-emitting area 120, an equation for calculating center energy at the edge light-emitting area 120 satisfies a following equation:

$$E 1 = \frac{4 k}{0.5 \sqrt{{A}^{2} + {b}^{2}}} + \frac{2 k}{0.5 \sqrt{{( 2 A + b )}^{2} + {A}^{2}}} + \frac{4 k}{0.5 \sqrt{{( 3 A )}^{2} + {( b )}^{2}}} + \frac{2 k}{0.5 \sqrt{{( 3 A )}^{2} + {( 2 A + b )}^{2}}} .$$

k is a coefficient that is a constant value, and E0=E1, so that average luminous brightness of the central light-emitting area 110 tends to be consistent with average luminous brightness of the edge light-emitting area 120. In an actual arrangement structure, it is difficult to achieve expected luminous brightness if an arrangement is only qualitatively designed. Therefore, a construction of model and a design of equations are conducive to achieving the average luminous brightness of the central luminous area 110 and the average luminous brightness of the edge light-emitting area 120 tend to be consistent, so as to enhance the brightness of the edge light-emitting area 120, thereby improving the overall quality of display images.

In some embodiments, please refer to FIG. 1, the edge light-emitting area 120 further includes at least one third rectangular light area 330 adjacent to the second rectangular light area 320 and located at a side of the second rectangular light area 320 away from the central light-emitting area 110. Four second light-emitting units 220 are respectively located at four corners of the third rectangular light area 330, and none of the second light-emitting units 220 is disposed in the third rectangular light area 330. A length of a side of the third rectangular light area 330 along the first direction is less than a length of a side of the third rectangular light area 330 along a direction perpendicular to the first direction which is equal to the length of each side of the first rectangular light area 310.

For example, the edge light-emitting area 120 includes the second sub area 122 adjacent to the first sub area 121 and including a plurality of the third rectangular light areas 330 arranged along the row direction and the column direction. Four second light-emitting units 220 are respectively located at four corners of each of the third rectangular light areas 330, and none of the second light-emitting units 220 is disposed in the third rectangular light area 330. A length of a corresponding side of the third rectangular light area 330 is less than a length of a corresponding side of the second rectangular light area 320 in an extension direction perpendicular to a side of the second sub area 122.

In an extension direction perpendicular to a side of the edge light-emitting area 120, a distance between adjacent two second emitting units 220 corresponding to the third rectangular light area 330 is less than a distance between adjacent two second emitting units 220 corresponding to the second rectangular light area 320.

The closer an area is to the edge of the backlight module 100, the less the distance between adjacent two second emitting units 220 along the first direction, which can reduce a difference of brightness between an edge area of the backlight module 100 and a center area of the backlight module 100, so as to improve luminous energy at any position of the edge light-emitting area 120 to enhance brightness of the edge light-emitting area 120, thereby improving the overall quality of display images.

In some embodiments, please refer to FIG. 1, the second sub area 122 includes a fifth side 650 and a sixth side 660. An extension direction of the fifth side 650 is parallel to the extension direction of the first side 610, an extension direction of the sixth side 660 is parallel to the extension direction of the second side 620, the fifth side 650 is adjacent to the first side 610, and the sixth side 660 is adjacent to the second side 620.

Lengths of corresponding sides of the third rectangular light area 330 in an extension direction parallel to a side of the second sub area 122 are equal that are A. A length of a side of the third rectangular light area 330 along the first direction is defined as c; for example, lengths of corresponding sides of the third rectangular light area 330 in an extension direction perpendicular to a side of the second sub area 122 are equal that are c.

A, b, and c satisfy a following equation:

$$\frac{2}{\sqrt{{A}^{2} + {A}^{2}}} + \frac{4}{\sqrt{{( 3 A )}^{2} + {A}^{2}}} + \frac{2}{\sqrt{{( 3 A )}^{2} + {( 3 A )}^{2}}} = \frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{\sqrt{{( 3 A )}^{2} + {( 2 A + b )}^{2}}} = \frac{2}{\sqrt{{A}^{2} + {c}^{2}}} + \frac{1}{\sqrt{{( 2 b + c )}^{2} + {A}^{2}}} + \frac{2}{\sqrt{{( 3 A )}^{2} + {( c )}^{2}}} + \frac{1}{\sqrt{{( 3 A )}^{2} + {( 2 b + c )}^{2}}} .$$

For example, the fifth side 650 extends along the row direction, and the sixth side 660 extends along the column direction. Lengths of sides of each third rectangular light area 330 corresponding to the fifth side 650 in the row direction are equal to the length of each side of the first rectangular light area 310 that is defined as A; lengths of sides of each third rectangular light area 330 corresponding to the fifth side 650 in the column direction are less than the length of the side of the second rectangular light area 320 and are c. Lengths of sides of each third rectangular light area 330 corresponding to the sixth side 660 in the column direction are equal to the length of each side of the first rectangular light area 310 that is defined as A; lengths of sides of each third rectangular light area 330 corresponding to the sixth side 660 in the row direction are less than the length of the side of the second rectangular light area 320 and are c.

Energy at a geometric center of the third rectangular light area 330 of the second sub area 122 is defined as E2, and E2 satisfies a following equation:

$$E 2 = \frac{4 k}{0.5 \sqrt{{A}^{2} + {c}^{2}}} + \frac{2 k}{0.5 \sqrt{{( 2 b + c )}^{2} + {A}^{2}}} + \frac{4 k}{0.5 \sqrt{{( 3 A )}^{2} + {( c )}^{2}}} + \frac{2 k}{0.5 \sqrt{{( 3 A )}^{2} + {( 2 b + c )}^{2}}} ,$$

When n is equal to 2, that is, only two gradient levels at the edge light-emitting area 120, an equation for calculating center energy at the edge light-emitting area 120 satisfies a following equation:

$$E 2 = \frac{4 k}{0.5 \sqrt{{A}^{2} + {c}^{2}}} + \frac{2 k}{0.5 \sqrt{{( 2 b + c )}^{2} + {A}^{2}}} + \frac{4 k}{0.5 \sqrt{{( 3 A )}^{2} + {( c )}^{2}}} + \frac{2 k}{0.5 \sqrt{{( 3 A )}^{2} + {( 2 b + c )}^{2}}} ,$$

and E0=E1=E2, so that average luminous brightness of the central light-emitting area 110 is consistent with average luminous brightness of the edge light-emitting area 120, so as to enhance brightness of the edge light-emitting area 120, thereby improving the overall quality of display images.

In some embodiments, please refer to FIG. 1, the edge light-emitting area 120 also includes at least one fourth rectangular light area 340 adjacent to the third rectangular light area 330 and located at a side of the third rectangular light area 330 away from the central light-emitting area 110. Four second light-emitting units 220 are respectively located at four corners of the fourth rectangular light area 340, and none of the second light-emitting units 220 is disposed in the fourth rectangular light area 340. A length of a side of the fourth rectangular light area 340 along the first direction is less than a length of a side of the fourth rectangular light area 340 along the direction perpendicular to the first direction which is equal to the length of each side of the first rectangular light area 310.

For example, the edge light-emitting area 120 also includes a third sub area 123 adjacent to the second sub area 122 and including a plurality of the fourth rectangular light areas 340 arranged along the row direction and/or the column direction. Four second light-emitting units 220 are respectively located at four corners of the fourth rectangular light area 340, and none of the second light-emitting units 220 is disposed in the fourth rectangular light area 340.

The third sub area 123 includes a seventh side 670 and/or an eighth side. For example, the seventh side 670 extends along the row direction, the eighth side extends along the column direction, the seventh side 670 is adjacent to the fifth side 650, and the eighth side is adjacent to the sixth side 660. Length of sides of each fourth rectangular light area 340 corresponding to the seventh side 670 in the row direction are equal to the length of each side of the first rectangular light area 310 that is defined as A; lengths of sides of each fourth rectangular light area 340 corresponding to the seventh side 670 in the column direction are less than a length of a side of the third rectangular light area 330 and is defined as d. Lengths of sides of each fourth rectangular light area 340 corresponding to the eighth side in the column direction are equal to the length of each side of the first rectangular light area 310 that is defined as A; lengths of sides of each fourth rectangular light area 340 corresponding to the eighth side in the row direction are less than the length of the side of the third rectangular light area 330 and are d. The seventh edge 670 is labeled and the eighth edge is not labeled in FIG. 1.

A, b, c, and d satisfy a following equation:

$$\frac{2}{\sqrt{{A}^{2} + {A}^{2}}} + \frac{4}{\sqrt{{( 3 A )}^{2} + {A}^{2}}} + \frac{2}{\sqrt{{( 3 A )}^{2} + {( 3 A )}^{2}}} = \frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{\sqrt{{( 3 A )}^{2} + {( 2 A + b )}^{2}}} = \frac{2}{\sqrt{{A}^{2} + {c}^{2}}} + \frac{1}{\sqrt{{( 2 b + c )}^{2} + {A}^{2}}} + \frac{2}{\sqrt{{( 3 A )}^{2} + {( c )}^{2}}} + \frac{1}{\sqrt{{( 3 A )}^{2} + {( 2 b + c )}^{2}}} = \frac{2}{\sqrt{{A}^{2} + {d}^{2}}} + \frac{1}{\sqrt{{( 2 c + d )}^{2} + {A}^{2}}} + \frac{2}{\sqrt{{( 3 A )}^{2} + {( d )}^{2}}} + \frac{1}{\sqrt{{( 3 A )}^{2} + {( 2 c + d )}^{2}}} .$$

Energy at a geometric center of the fourth rectangular light area 340 of the third sub area 123 is defined as E3, and E3 satisfies a following equation:

$$E 3 = \frac{4 k}{0.5 \sqrt{{A}^{2} + {d}^{2}}} + \frac{2 k}{0.5 \sqrt{{( 2 c + d )}^{2} + {A}^{2}}} + \frac{4 k}{0.5 \sqrt{{( 3 A )}^{2} + {( d )}^{2}}} + \frac{2 k}{0.5 \sqrt{{( 3 A )}^{2} + {( 2 c + d )}^{2}}} ,$$

When n is equal to 3, that is, only three gradient levels at the edge light-emitting area 120, an equation for calculating center energy at the edge light-emitting area 120 satisfies a following equation:

$$E 3 = \frac{4 k}{0.5 \sqrt{{A}^{2} + {d}^{2}}} + \frac{2 k}{0.5 \sqrt{{( 2 c + d )}^{2} + {A}^{2}}} + \frac{4 k}{0.5 \sqrt{{( 3 A )}^{2} + {( d )}^{2}}} + \frac{2 k}{0.5 \sqrt{{( 3 A )}^{2} + {( 2 c + d )}^{2}}} ,$$

and E0=E1=E2=E3, so that average luminous brightness of the central light-emitting area 110 is consistent with average luminous brightness of the edge light-emitting area 120, so as to enhance the brightness of the edge light-emitting area 120, thereby improving the overall quality of display images.

For convenience of labeling, the first sub area 121, the second sub area 122, and the third sub area 123 are only partially framed in the figures.

In some embodiments, gradual levels of center energy at the edge light-emitting area 120 can increase, and will not be further described here.

Assuming a linear relationship between b, c, d, and A when solving an equation, when n is equal to 1, A and b satisfy a following equation:

$$\frac{2 ( 3 \sqrt{10} + 10 \sqrt{2}}{15 A} = \frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{\sqrt{{( 3 A )}^{2} + {( 2 A + b )}^{2}}} ;$$

when n is equal to 2, A, b, and c satisfy a following equation:

$$\frac{2 ( 3 \sqrt{10} + 10 \sqrt{2}}{15 A} = \frac{2}{\sqrt{{A}^{2} + {b}^{2}}} + \frac{1}{\sqrt{{( b + 2 c )}^{2} + {A}^{2}}} + \frac{1}{\sqrt{{( 2 A + b )}^{2} + {( A )}^{2}}} + \frac{2}{\sqrt{{( 3 A )}^{2} + {( b )}^{2}}} + \frac{1}{\sqrt{{( 2 c + b )}^{2} + {( 3 A )}^{2}}} + \frac{1}{\sqrt{{( 2 A + b )}^{2} + {( 3 A )}^{2}}} = \frac{2}{\sqrt{{A}^{2} + {c}^{2}}} + \frac{1}{\sqrt{{( 2 b + c )}^{2} + {A}^{2}}} + \frac{2}{\sqrt{{( 3 A )}^{2} + {( c )}^{2}}} + \frac{1}{\sqrt{{( 3 A )}^{2} + {( 2 b + c )}^{2}}} ;$$

when n is equal to 3, A, b, c, and d satisfy a following equation:

$$\frac{2 ( 3 \sqrt{10} + 10 \sqrt{2}}{15 A} = \frac{2}{\sqrt{{A}^{2} + {b}^{2}}} + \frac{1}{\sqrt{{( b + 2 c )}^{2} + {A}^{2}}} + \frac{1}{\sqrt{{( 2 A + b )}^{2} + {( A )}^{2}}} + \frac{2}{\sqrt{{( 3 A )}^{2} + {( b )}^{2}}} + \frac{1}{\sqrt{{( 2 A + b )}^{2} + {( 3 A )}^{2}}} + \frac{1}{\sqrt{{( 2 c + b )}^{2} + {( 3 A )}^{2}}} = \frac{2}{\sqrt{{A}^{2} + {c}^{2}}} + \frac{1}{\sqrt{{( c + 2 d )}^{2} + {A}^{2}}} + \frac{1}{\sqrt{{( 2 A + c )}^{2} + {( A )}^{2}}} + \frac{2}{\sqrt{{( 3 A )}^{2} + {( c )}^{2}}} + \frac{1}{\sqrt{{( 2 d + c )}^{2} + {( 3 A )}^{2}}} + \frac{1}{\sqrt{{( 2 b + c )}^{2} + {( 3 A )}^{2}}} = \frac{2}{\sqrt{{A}^{2} + {d}^{2}}} + \frac{1}{\sqrt{{( 2 c + d )}^{2} + {A}^{2}}} + \frac{2}{\sqrt{{( 3 A )}^{2} + {( d )}^{2}}} + \frac{1}{\sqrt{{( 3 A )}^{2} + {( 2 c + d )}^{2}}} .$$

By simplifying the above-mentioned equations, it can be concluded that:
when n is equal to 1, b and A satisfy a following equation: b=0.5071A;
when n is equal to 2, b and A satisfy a following equation: b=0.8875A; c and A satisfy a following equation: c=0.4792A; and
when n is equal to 3, b and A satisfy a following equation: b=0.9408A; c and A satisfy a following equation: c=0.8708A; and d and A satisfy a following equation: d=0.6125A.

In the above-mentioned equations, E0, E1, E2, and E3 cannot be completely equal (cannot be solved) and can only be approximately solved.

Model verification: taking the first light-emitting units 210 and the second emitting units 220 as Mini LEDs as an example, A can range from 1 mm to 7 mm. Assuming A is equal to 3 mm, when n is equal to 1, E0=E1, and b is equal to 1.52 mm; when n is equal to 2, E0=E1=E2, b is equal to 2.65 mm, and c is equal to 1.6 mm; when n is equal to 3, E0=E1=E2=E3, b is equal to 2.9 mm, c is equal to 2.6 mm, and d is equal to 1.7 mm. As n increases, that is, when a quantity of the gradient levels increases, a sudden change of a gradient distance decreases, transition of brightness is smoother, thereby improving a display effect.

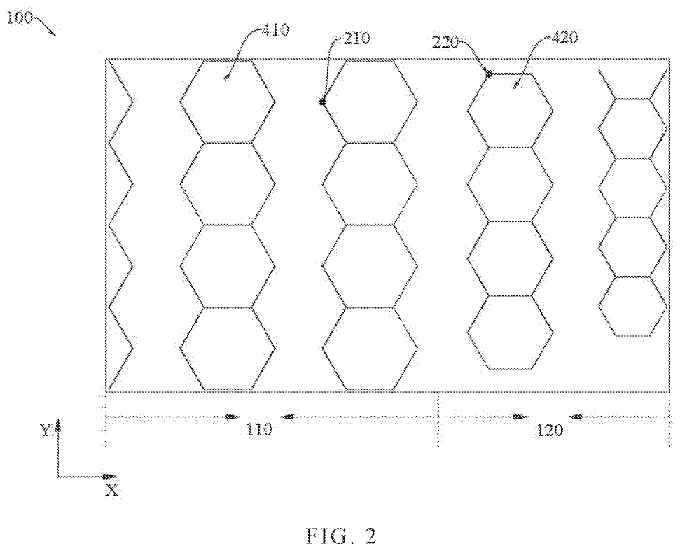

In some embodiments, please refer to FIG. 2, the central light-emitting area 110 includes at least one first regular hexagonal light area 410, six first light-emitting units 210 are respectively located at six corners of the first regular hexagonal light area 410, and none of the first light-emitting units 210 is disposed in the first regular hexagonal light area 410. The edge light-emitting area 120 includes at least one second regular hexagonal light area 420, six second emitting units 220 are respectively located at six corners of the second regular hexagonal light area 420, and none of the second emitting units 220 is disposed in the second regular hexagonal light area 420. A length of any side of the first regular hexagonal light area 410 is greater than a length of any side of the second regular hexagonal light area 420.

The light-emitting units are arranged in a regular hexagonal shape, which can achieve a better uniformity of light. Specifically, since the second regular hexagonal light area 420 and the first regular hexagonal light area 410 are spaced apart, the farther away from the center of the backlight module 100, the smaller a size of the regular hexagonal light area, thereby improving luminous energy of the edge light-emitting area 120 to enhance brightness of the edge emitting area 120, so as to improve the overall quality of display images.

In some embodiments, please refer to FIG. 2, the light-emitting units between the first regular hexagonal light region 410 of the central light-emitting area 110 and adjacent second regular hexagonal light area 420 is in a non-regular hexagonal shape.

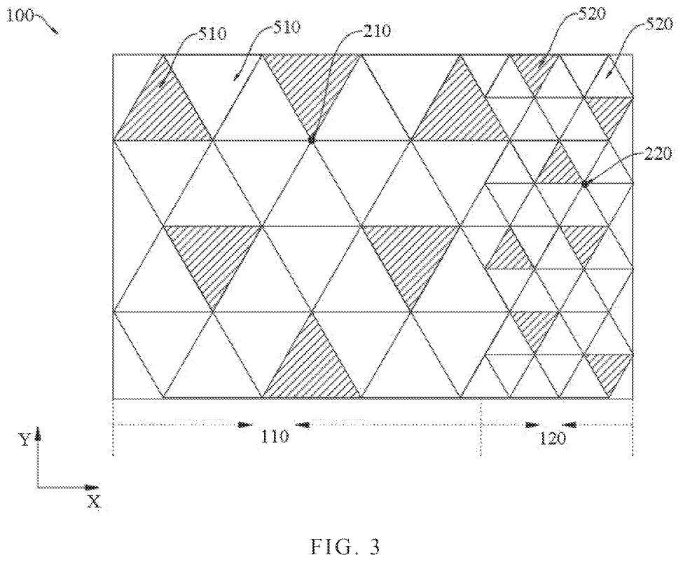

In some embodiments, refer to FIG. 3, the central light-emitting area 110 includes at least one first regular triangle light area 510, three first light-emitting units 210 are respectively located at three corners of the first regular triangle light area 510, and none of the first light-emitting units 210 is disposed in the first regular triangle light area 510. The edge light-emitting area 120 includes at least one second regular triangle light area 520, three second light-emitting units 220 are respectively located at three corners of the second regular triangle light area 520, and none of the second light-emitting units 220 is disposed in the second regular triangle light area 520. A length of any side of the first regular triangle light area 510 is greater than a length of any side of the second regular triangle light area 520.

The light-emitting units are arranged in a regular triangle shape, which facilitates an arrangement of the light-emitting units. For example, the length of any side of the second regular triangle light area 520 is half of the length of any side of the first regular triangle light area 510, so that the second light-emitting units 220 can be arranged regularly. For example, each shadow area in FIG. 3 represents a driving unit corresponding to the first regular triangle light area 510 or the second regular triangle light area 520. The driving unit may drive one light area separately, and adjacent light areas can be driven in parallel, thereby reducing quantities of the driving units and driving wirings.

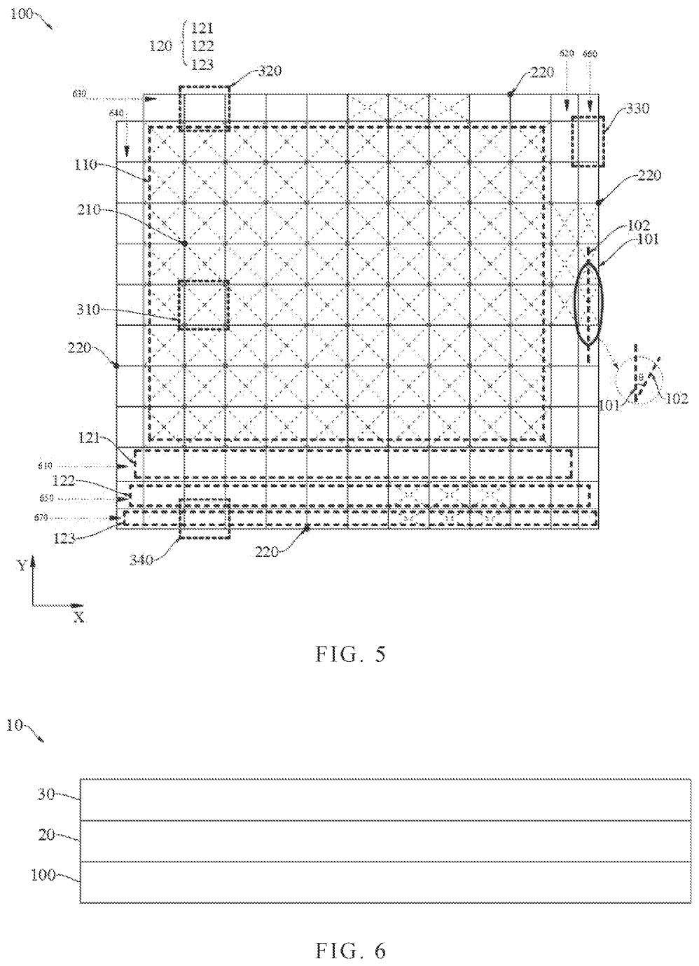

In some embodiments, please refer to FIG. 5, a light shape of the second light-emitting unit 220 is in an ellipsoid shape. The backlight module 100 includes at least a first edge 101, and an included angle θ between the first edge 101 and a long axis of the light shape of the corresponding second light-emitting unit 220 is less than or equal to 5 degrees in a top view direction of the backlight module 100.

The light shape of the second light-emitting unit 220 presents the ellipsoid defined by diffusion intensity of light energy from different directions. A shape of an orthographic projection of the light shape of the second light-emitting unit 220 in the top view direction of the backlight module 100 is an ellipse defined with a long axis and a short axis. The diffusion intensity of the light energy in a long axis direction is high, and the diffusion intensity of the light energy in a short axis direction is low. Therefore, the short axis is oriented towards the central light-emitting area 110 and the long axis tends to be parallel to a corresponding edge, so that more light energy can be retained at the edge light-emitting area 120, which can improve the luminous energy of the edge light-emitting area 120 to enhance brightness of the edge light-emitting area 120, thereby improving the overall quality of display images.

In some embodiments, the backlight module 100 also includes an optical device area and an optical edge area, and the central light-emitting area 110 is designed surrounding the optical device area and the optical edge area. The optical edge area is provided surrounding the optical device area, and the optical device area is provided corresponding to an optical device, such as a camera, an infrared sensor, or a distance sensor.

In some embodiments, the backlight module 100 also includes a plurality of third light-emitting units located at the optical edge area, and the distance between adjacent two first light-emitting units 210 is greater than a distance between at least adjacent two third light-emitting units.

Appearance at the optical device area and the optical edge area can be optimized to avoid affecting a display effect caused by sudden dimming of light close to the optical device area.

In some embodiments, the backlight module 100 also includes a driving layer configured to drive the first light-emitting units 210, the second light-emitting units 220, and the third light-emitting units.

In some embodiments, each of the first light-emitting unit 210, the second light-emitting unit 220, and the third light-emitting unit may be a Micro LED or a Mini LED, and is not specifically limited.

By designing a distance of the second light-emitting units at the edge light-emitting area being less than a distance of the first light-emitting units at the central light-emitting area along the direction from the center to the edge of the backlight module, the present disclosure can improve luminous energy of the edge light-emitting area to enhance brightness of the edge light-emitting area, thereby improving the overall quality of display images.

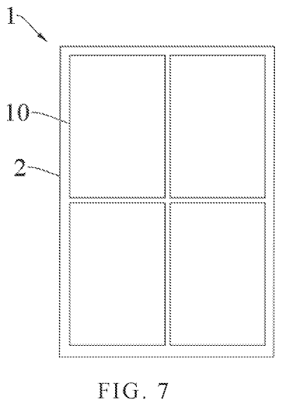

Please refer to FIG. 6, an embodiment of the present disclosure also provides a display module 10 including a backlight module 100 as described in any of the above-mentioned embodiments.

In some embodiments, please refer to FIG. 6, the display module 10 also includes an array substrate 20, a liquid crystal layer 30, a color film layer, an upper polarizing layer, and a lower polarizing layer.

In some embodiments, the array substrate 20 includes a substrate, an active layer located on the substrate, a first insulation layer located on the active layer, a gate layer located on the first insulation layer, a second insulation layer located on the gate layer, a source drain layer located on the second insulation layer, and a third insulation layer located on the source drain layer.

In some embodiments, a material of the substrate may be a hard material, for example, the substrate may be a glass; or, the material of the substrate may be a flexible material, such as polyimide, and is not specifically limited here.

Please refer to FIG. 7, an embodiment of the present disclosure also provides a splicing display device 1 including at least two spliced display modules, each of the display modules 10 can be the above-mentioned display module 10.

Brightness of the edge of the display module 10 tends to be consistent with the brightness of the center of the display module 10, thereby reducing a width of a splicing seam of the splicing display device 1 during splicing, so as to improve a display effect of the splicing display device 1.

In some embodiments, the display device further includes a device body 2 integrated with the display module 10.

In some embodiments, the device body 2 may include a middle frame, a frame adhesive, etc., and the display device may be a display terminal such as a mobile phone, a tablet, a TV, a giant screen, etc., and is not limited here.

Embodiments of the present disclosure disclose the backlight module, the display module, and the splicing display device. The backlight module includes the central light-emitting area and the edge light-emitting area disposed at the side of the central light-emitting area along the first direction, and includes the plurality of first light-emitting units located at the central light-emitting area and the plurality of second light-emitting units located at the edge light-emitting area. The direction from the center of the backlight module to the edge of the backlight module is defined as the first direction, and the distance between adjacent two of the first light-emitting units along the first direction is greater than the distance between adjacent two of the second light-emitting units along the first direction. By designing the distance of the second light-emitting units at the edge light-emitting area being less than the distance of the first light-emitting units at the central light-emitting area along the direction from the center to the edge of the backlight module, the present disclosure can improve luminous energy of the edge light-emitting area to enhance brightness of the edge light-emitting area, thereby improving the overall quality of display images.

It can be understood that equivalent substitutions or changes can be made based on the technical solutions and an invention concept of the present disclosure for those skilled in the art; however, all the changes or the substitutions should fall within a protection scope of claims attached to the present disclosure.

What is claimed is:

1. A backlight module, comprising a central light-emitting area and an edge light-emitting area disposed at a side of the central light-emitting area along a first direction, wherein the backlight module comprises:
a plurality of first light-emitting units disposed in the central light-emitting area; and
a plurality of second light-emitting units disposed in the edge light-emitting area;
wherein a direction from a center of the backlight module to an edge of the backlight module is defined as the first direction, and a distance between adjacent two of the first light-emitting units along the first direction is greater than a distance between adjacent two of the second light-emitting units along the first direction.

2. The backlight module of claim 1, wherein the distance between the adjacent two of the second light-emitting units along the first direction gradually decreases.

3. The backlight module of claim 2, wherein distances between every adjacent two of the first light-emitting units along the first direction are equal.

4. The backlight module of claim 3, wherein the central light-emitting area comprises at least one first rectangular light area, four of the first light-emitting units are respectively located at four corners of the first rectangular light area, and none of the first light-emitting units is disposed in the first rectangular light area; and
wherein the first rectangular light area is in a square shape.

5. The backlight module of claim 4, wherein the edge light-emitting area comprises at least one second rectangular light area adjacent to the central light-emitting area, four of the second light-emitting units are respectively located at four corners of the second rectangular light area, and none of the second light-emitting units is disposed in the second rectangular light area;
a length of a side of the second rectangular light area along the first direction is less than a length of a side of the second rectangular light area along a direction perpendicular to the first direction, and the length of the side of the second rectangular light area along the direction perpendicular to the first direction is equal to a length of each side of the first rectangular light area.

6. The backlight module of claim 5, wherein the length of each side of the first rectangular light area is defined as A, and the length of the side of the second rectangular light area along the first direction is defined as b;
wherein A and b satisfy a following equation:
$$\frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{\sqrt{{( 3 A )}^{2} + {( 2 A + b )}^{2}}} = \frac{2}{\sqrt{{A}^{2} + {A}^{2}}} + \frac{4}{\sqrt{{( 3 A )}^{2} + {A}^{2}}} + \frac{2}{\sqrt{{( 3 A )}^{2} + {( 3 A )}^{2}}} .$$

7. The backlight module of claim 6, wherein the edge light-emitting area further comprises at least one third rectangular light area adjacent to the second rectangular light area and located at a side of the second rectangular light area away from the central light-emitting area; four of the second light-emitting units are respectively located at four corners of the third rectangular light area, and none of the second light-emitting units is disposed in the third rectangular light area;
wherein a length of a side of the third rectangular light area along the first direction is defined as c, and A, b, and c satisfy a following equation:
$$\frac{2}{\sqrt{{A}^{2} + {b}^{2}}} + \frac{1}{\sqrt{{( 2 A + b )}^{2} + {A}^{2}}} + \frac{2}{\sqrt{{( 3 A )}^{2} + {( b )}^{2}}} + \frac{1}{\sqrt{{( 3 A )}^{2} + {( 2 A + b )}^{2}}} = \frac{2}{\sqrt{{A}^{2} + {c}^{2}}} + \frac{1}{\sqrt{{( 2 b + c )}^{2} + {A}^{2}}} + \frac{2}{\sqrt{{( 3 A )}^{2} + {( c )}^{2}}} + \frac{1}{\sqrt{{( 3 A )}^{2} + {( 2 b + c )}^{2}}} .$$

8. The backlight module of claim 1, wherein the central light-emitting area comprises at least one first regular hexagonal light area, six of the first light-emitting units are respectively located at six corners of the first regular hexagonal light area, and none of the first light-emitting units is disposed in the first regular hexagonal light area;
the edge light-emitting area comprises at least one second regular hexagonal light area, six of the second emitting units are respectively located at six corners of the second regular hexagonal light area, and none of the second light-emitting units is disposed in the second regular hexagonal light area; and
wherein a length of any side of the first regular hexagonal light area is greater than a length of any side of the second regular hexagonal light area.

9. The backlight module of claim 1, wherein the central light-emitting area comprises at least one first regular triangle light area, three of the first light-emitting units are respectively located at three corners of the first regular triangle light area, and none of the first light-emitting units is disposed in the first regular triangle light area; and
the edge light-emitting area comprises at least one second regular triangle light area, three of the second light-emitting units are respectively located at three corners of the second regular triangle light area, and none of the second light-emitting units is disposed in the second regular triangle light area;
wherein a length of any side of the first regular triangle light area is greater than a length of any side of the second regular triangle light area.

10. The backlight module of claim 1, wherein a light shape of the second light-emitting units is in an ellipsoid shape;
wherein the backlight module comprises at least a first edge, and an included angle between the first edge and a long axis of the light shape corresponding to one of the second light-emitting units is less than or equal to 5 degrees in a top view direction of the backlight module.

11. A display module, comprising a backlight module, wherein the backlight module comprises a central light-emitting area and an edge light-emitting area disposed at a side of the central light-emitting area along a first direction, wherein the backlight module comprises:
a plurality of first light-emitting units disposed in the central light-emitting area; and
a plurality of second light-emitting units disposed in the edge light-emitting area;
wherein a direction from a center of the backlight module to an edge of the backlight module is defined as the first direction, and a distance between adjacent two of the first light-emitting units along the first direction is greater than a distance between adjacent two of the second light-emitting units along the first direction.

12. The display module of claim 11, wherein the distance between the adjacent two of the second light-emitting units along the first direction gradually decreases.

13. The display module of claim 12, wherein distances between every adjacent two of the first light-emitting units along the first direction are equal.

14. The display module of claim 13, wherein the central light-emitting area comprises at least one first rectangular light area, four of the first light-emitting units are respectively located at four corners of the first rectangular light area, and none of the first light-emitting units is disposed in the first rectangular light area; and
wherein the first rectangular light area is in a square shape.

15. The display module of claim 14, wherein the edge light-emitting area comprises at least one second rectangular light area adjacent to the central light-emitting area, four of the second light-emitting units are respectively located at four corners of the second rectangular light area, and none of the second light-emitting units is disposed in the second rectangular light area;
a length of a side of the second rectangular light area along the first direction is less than a length of a side of the second rectangular light area along a direction perpendicular to the first direction, and the length of the side of the second rectangular light area along the direction perpendicular to the first direction is equal to a length of each side of the first rectangular light area.

16. The display module of claim 11, wherein the central light-emitting area comprises at least one first regular hexagonal light area, six of the first light-emitting units are respectively located at six corners of the first regular hexagonal light area, and none of the first light-emitting units is disposed in the first regular hexagonal light area;
the edge light-emitting area comprises at least one second regular hexagonal light area, six of the second emitting units are respectively located at six corners of the second regular hexagonal light area, and none of the second light-emitting units is disposed in the second regular hexagonal light area; and
wherein a length of any side of the first regular hexagonal light area is greater than a length of any side of the second regular hexagonal light area.

17. The display module of claim 11, wherein the central light-emitting area comprises at least one first regular triangle light area, three of the first light-emitting units are respectively located at three corners of the first regular triangle light area, and none of the first light-emitting units is disposed in the first regular triangle light area; and
the edge light-emitting area comprises at least one second regular triangle light area, three of the second light-emitting units are respectively located at three corners of the second regular triangle light area, and none of the second light-emitting units is disposed in the second regular triangle light area;
wherein a length of any side of the first regular triangle light area is greater than a length of any side of the second regular triangle light area.

18. The display module of claim 11, wherein a light shape of the second light-emitting units is in an ellipsoid shape;
wherein the backlight module comprises at least a first edge, and an included angle between the first edge and a long axis of the light shape corresponding to one of the second light-emitting units is less than or equal to 5 degrees in a top view direction of the backlight module.

19. A splicing display device, comprising at least two spliced display modules, wherein each of the display modules comprises a backlight module comprising a central light-emitting area and an edge light-emitting area disposed at a side of the central light-emitting area along a first direction, and the backlight module comprises:
a plurality of first light-emitting units disposed in the central light-emitting area; and
a plurality of second light-emitting units disposed in the edge light-emitting area;
wherein a direction from a center of the backlight module to an edge of the backlight module is defined as the first direction, and a distance between adjacent two of the first light-emitting units along the first direction is greater than a distance between adjacent two of the second light-emitting units along the first direction.

20. The splicing display device of claim 19, wherein the distance between the adjacent two of the second light-emitting units along the first direction gradually decreases.
